(19) United States
(12) Patent Application Publication
(10) Pub. No.: US 2016/0240614 A1
(43) Pub. Date: Aug. 18, 2016

(54) SEMICONDUCTOR DEVICE AND SEMICONDUCTOR PACKAGE

(71) Applicant: Kabushiki Kaisha Toshiba, Tokyo (JP)

(72) Inventors: Takashi Okuhata, Komatsu Ishikawa (JP); Syotaro Ono, Kanazawa Ishikawa (JP)

(21) Appl. No.: 14/843,441

(22) Filed: Sep. 2, 2015

(30) Foreign Application Priority Data
Feb. 18, 2015 (JP) 2015-029878

(51) Int. Cl. H01L 29/06; H01L 29/417; H01L 29/423

(52) U.S. Cl. CPC H01L 29/0696; H01L 29/42356; H01L 29/417

(57) ABSTRACT

A semiconductor device according to an embodiment includes a first semiconductor region of a first conductivity type, a second semiconductor region of a second conductivity type, a third semiconductor region of the first conductivity type, a first electrode, a gate electrode, a third insulating layer, a second electrode, a third electrode, and a fourth electrode. The third insulating layer is provided between the gate electrode and the first semiconductor region, between the gate electrode and the second semiconductor region, and between the gate electrode and the third semiconductor region. The second electrode is electrically connected to the third semiconductor region. The third electrode is spaced from the second electrode. The third electrode is electrically connected to the gate electrode. The fourth electrode is electrically connected to the first electrode. The fourth electrode is spaced from the second electrode and the third electrode.

### CROSS-REFERENCE TO RELATED APPLICATIONS

This application is based upon and claims the benefit of priority from Japanese Patent Application No. 2015-029878, filed on Feb. 18, 2015; the entire contents of which are incorporated herein by reference.

### FIELD

Embodiments described herein relate generally to a semiconductor device and a semiconductor package.

### BACKGROUND

Semiconductor devices such as MOSFET (metal oxide semiconductor field effect transistor) and IGBT (insulated gate bipolar transistor) are used for e.g. power control.

A MOSFET and IGBT may be provided with an additional electrode such as a field plate electrode below the gate electrode. The characteristics of the semiconductor device are changed with the potential of the additional electrode.

In such semiconductor devices, preferably, the potential of the additional electrode is set depending on the usage mode of the semiconductor device.

### BRIEF DESCRIPTION OF THE DRAWINGS

FIGS. 1 and 2 are plan views showing part of the semiconductor device according to the first embodiment;

FIG. 3 is a schematic sectional view taken along A-A′ of FIG. 1, showing part of the semiconductor device according to the first embodiment;

FIG. 4 is a schematic sectional view taken along B-B′ of FIG. 1, showing part of the semiconductor device according to the first embodiment;

FIG. 5 is a schematic sectional view taken along C-C′ of FIG. 1, showing part of the semiconductor device according to the first embodiment;

FIG. 6 is a schematic sectional view taken along D-D′ of FIG. 1, showing part of the semiconductor device according to the first embodiment;

FIG. 7 is a schematic view showing the packaged semiconductor device according to the first embodiment;

FIGS. 8A to 14B are schematic process sectional views showing the process for manufacturing the semiconductor device according to this embodiment;

FIG. 15 is a schematic plan view showing part of a semiconductor device according to a second embodiment;

FIG. 16 is a schematic sectional view taken along A-A′ of FIG. 15, showing part of the semiconductor device according to the second embodiment;

FIG. 17 is a schematic plan view showing part of a semiconductor device according to a third embodiment;

FIG. 18 is a schematic sectional view taken along A-A′ of FIG. 17, showing part of the semiconductor device according to the third embodiment;

FIG. 19 is a schematic plan view showing part of a semiconductor device according to a fourth embodiment;

FIG. 20 is a schematic sectional view taken along A-A′ of FIG. 19, showing part of the semiconductor device according to the fourth embodiment; and

FIG. 21 is a schematic sectional view showing part of a semiconductor device according to a fifth embodiment.

### DETAILED DESCRIPTION

A semiconductor device according to an embodiment includes a first semiconductor region of a first conductivity type, a second semiconductor region of a second conductivity type, a third semiconductor region of the first conductivity type, a first electrode, a gate electrode, a third insulating layer, a second electrode, a third electrode, and a fourth electrode. The second semiconductor region is selectively provided on the first semiconductor region. The third semiconductor region is selectively provided on the second semiconductor region. The first electrode is provided in the first semiconductor region with a first insulating layer interposed. The gate electrode is provided on the first electrode with a second insulating layer interposed. The third insulating layer is provided between the gate electrode and the first semiconductor region, between the gate electrode and the second semiconductor region, and between the gate electrode and the third semiconductor region. The second electrode is electrically connected to the third semiconductor region. The third electrode is spaced from the second electrode. The third electrode is electrically connected to the gate electrode. The fourth electrode is electrically connected to the first electrode. The fourth electrode is spaced from the second electrode and the third electrode.

Embodiments of the invention will now be described with reference to the drawings.

The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

Arrows X, Y, and Z in the drawings represent three directions orthogonal to each other. For instance, the direction represented by arrow X (X-direction) and the direction represented by arrow Y (Y-direction) are directions parallel to the major surface of the semiconductor substrate. The direction represented by arrow Z (Z-direction) represents the direction perpendicular to the major surface of the semiconductor substrate.

In this specification and the drawings, components similar to those described previously are labeled with like reference numerals, and the detailed description thereof is omitted appropriately.

The embodiments described below may be practiced by reversing the p-type and the n-type of each semiconductor region.

### First Embodiment

The semiconductor device 100 according to a first embodiment is e.g. a MOSFET.

The semiconductor device 100 according to the first embodiment includes an n-type (first conductivity type) drain region 10 (fourth semiconductor region), an n-type semiconductor region 12 (first semiconductor region), a p-type (second conductivity type) base region 20 (second semiconductor region), an n-type source region 22 (third semiconductor region), a buried electrode 14 (first electrode), a gate electrode 24, an insulating layer 16 (first insulating layer), an insulating layer 18 (second insulating layer), an insulating layer 26 (third insulating layer), a drain electrode 30 (fifth electrode), a source electrode pad 32 (second electrode), a gate electrode pad 38 (third electrode), an electrode pad 36 (fourth electrode), an extraction electrode 42 (first extraction electrode), and an extraction electrode 40 (second extraction electrode).

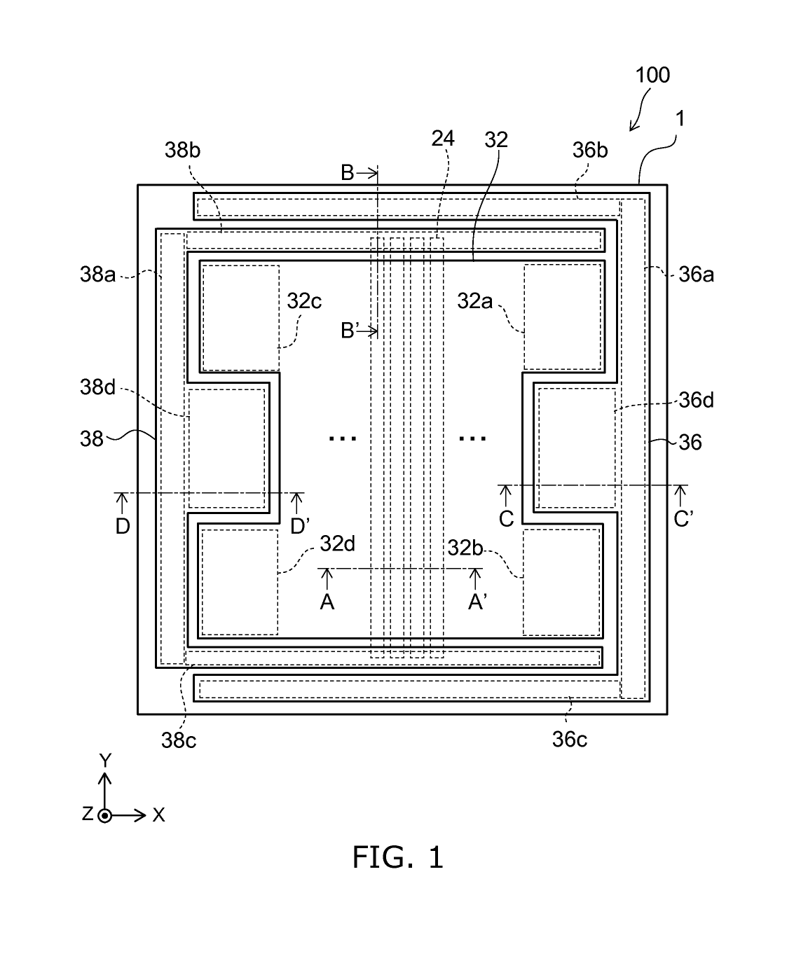

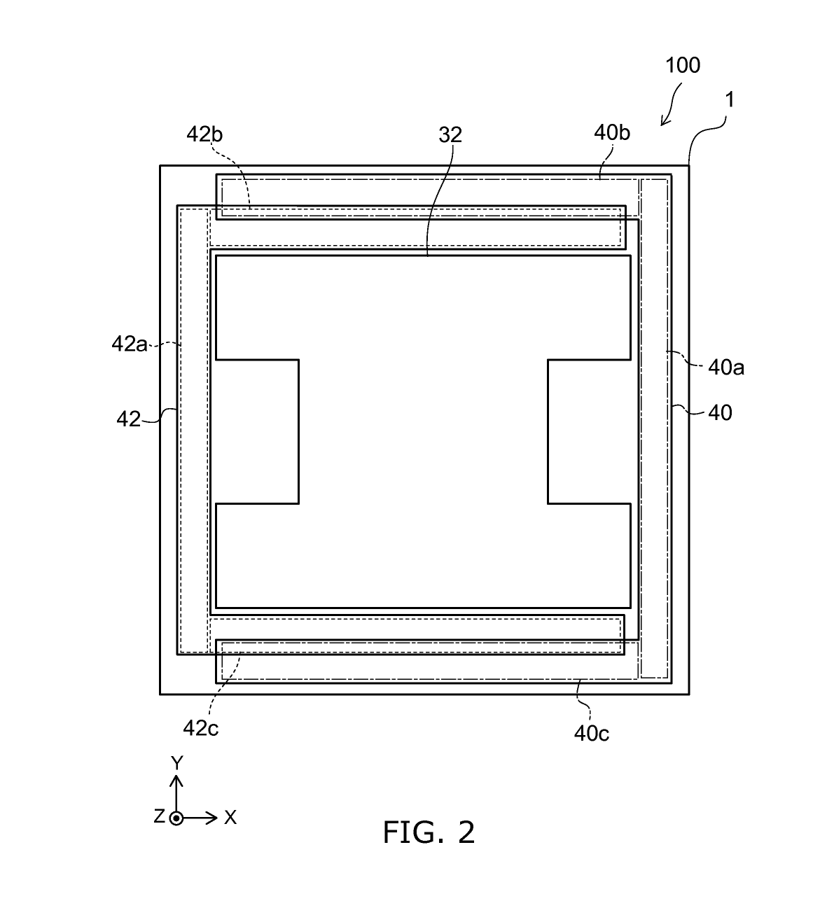

FIGS. 1 and 2 are plan views showing part of the semiconductor device 100 according to the first embodiment.

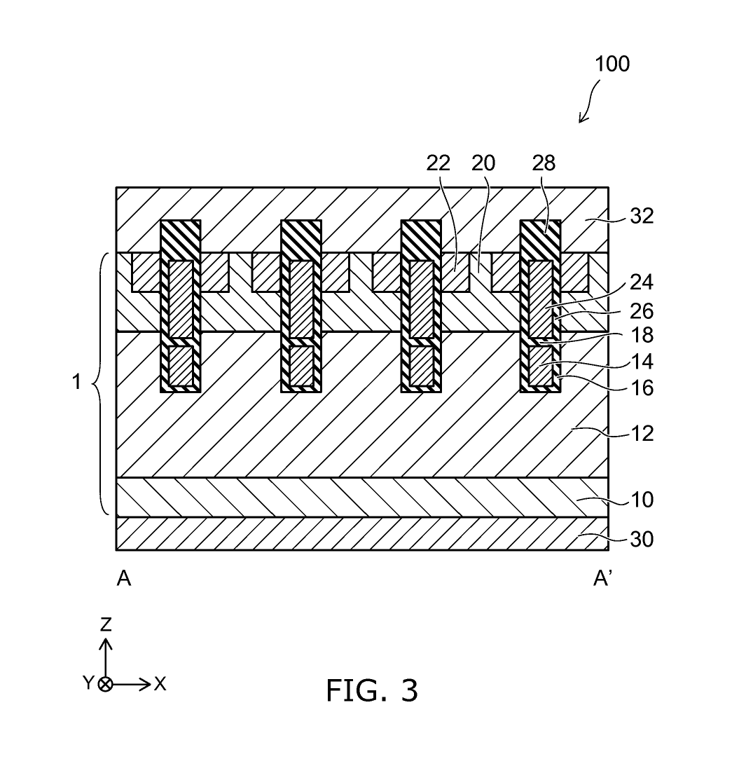

FIG. 3 is a schematic sectional view taken along A-A′ of FIG. 1, showing part of the semiconductor device 100 according to the first embodiment.

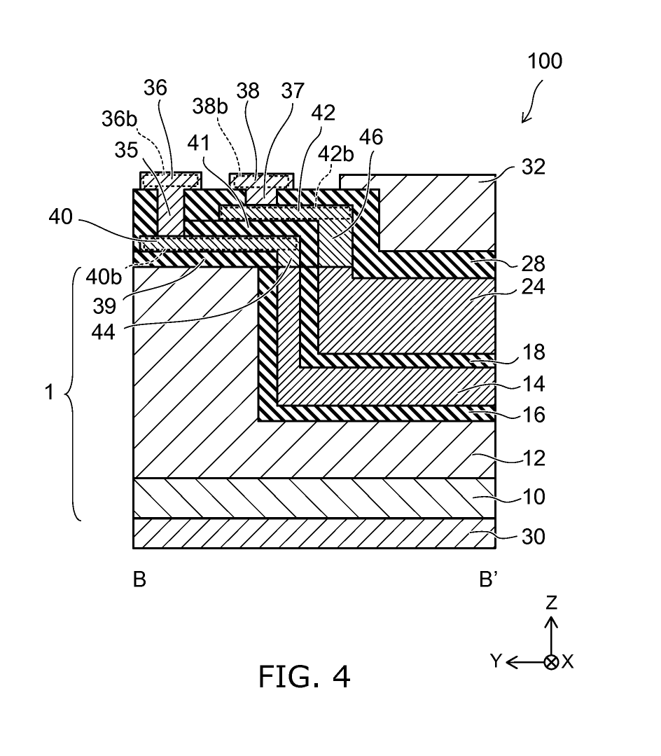

FIG. 4 is a schematic sectional view taken along B-B′ of FIG. 1, showing part of the semiconductor device 100 according to the first embodiment.

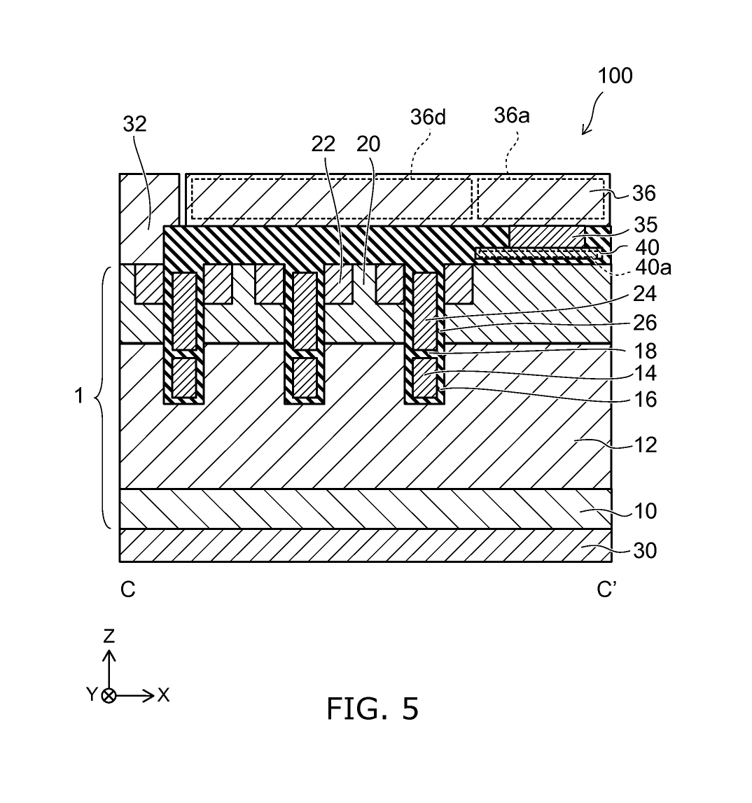

FIG. 5 is a schematic sectional view taken along C-C′ of FIG. 1, showing part of the semiconductor device 100 according to the first embodiment.

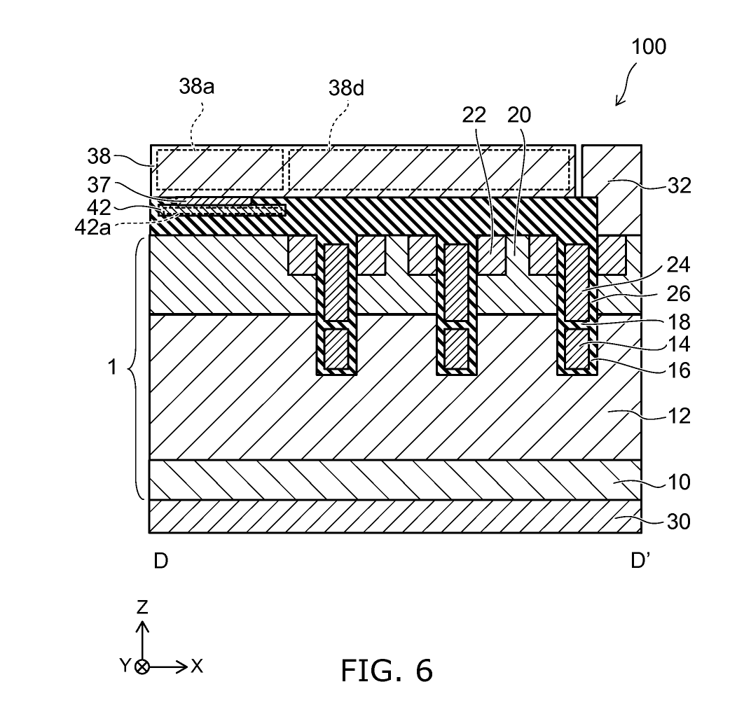

FIG. 6 is a schematic sectional view taken along D-D′ of FIG. 1, showing part of the semiconductor device 100 according to the first embodiment.

In FIG. 1, the insulating layers are not shown. In FIG. 1, part of the gate electrodes 24 provided in a plurality are shown by dashed lines.

In FIG. 2, the electrode pad 36, the gate electrode pad 38, the insulating layers and the like are not shown in order to describe the configuration of the extraction electrode 40 and the extraction electrode 42.

As shown in FIG. 1, the source electrode pad 32, the electrode pad 36, and the gate electrode pad 38 are provided on a first major surface (front surface) of the semiconductor substrate 1 (hereinafter simply referred to as substrate 1). The source electrode pad 32, the electrode pad 36, and the gate electrode pad 38 are spaced from each other.

The gate electrode 24 is provided in a plurality below the source electrode pad 32 in the substrate 1. The gate electrode 24 extends in the Y-direction (first direction). The gate electrode 24 is provided in a plurality in the X-direction (second direction).

The electrode pad 36 includes a portion 36a (second portion) extending in the Y-direction. The electrode pad 36 includes a portion 36b (third portion) and a portion 36c (fourth portion) extending in the X-direction. The portion 36b is provided in contact with one Y-direction end of the portion 36a. The portion 36c is provided in contact with the other Y-direction end of the portion 36a.

The gate electrode pad 38 includes a portion 38a (second portion) extending in the Y-direction. The gate electrode pad 38 includes a portion 38b (third portion) and a portion 38c (fourth portion) extending in the X-direction. The portion 38b is provided in contact with one Y-direction end of the portion 38a. The portion 38c is provided in contact with the other Y-direction end of the portion 38a.

The extending direction of the portion 36a and the portion 38a is the same as e.g. the extending direction of the gate electrode 24.

The distance between the portion 36b and the source electrode pad 32 is larger than the distance between the portion 38b and the source electrode pad 32.

The electrode pad 36 includes a portion 36d (first portion) projected in the direction (hereinafter referred to as—X-direction) opposite to the X-direction. The portion 36d is connected to the portion 36a. The gate electrode pad 38 includes a portion 38d (first portion) projected in the X-direction. The portion 38d is connected to the portion 38a. The portion 38d and the portion 36d are opposed to each other across the source electrode pad 32.

The source electrode pad 32 includes portions 32a (first portion) and 32b (second portion) provided on the electrode pad 36 side and projected in the X-direction. The source electrode pad 32 includes portions 32c (third portion) and 32d (fourth portion) provided on the gate electrode pad 38 side and projected in the—X-direction (fourth direction).

At least part of the portion 36d of the electrode pad 36 is provided between the portions 32a and 32b of the source electrode pad 32 in the Y-direction in plan view.

At least part of the portion 38d of the gate electrode pad 38 is provided between the portions 32c and 32d of the source electrode pad 32 in the Y-direction in plan view.

The term “plan view” means that e.g. the semiconductor device 100 is viewed in the Z-direction (third direction).

At least part of the source electrode pad 32 is provided between the portion 36b and the portion 36c in the Y-direction in plan view. At least part of the source electrode pad 32 is provided between the portion 38b and the portion 38c in the Y-direction in plan view.

Part of the portion 38b of the gate electrode pad 38 is provided between the portion 36b of the electrode pad 36 and the source electrode pad 32 in the Y-direction in plan view. Likewise, part of the portion 38c of the gate electrode pad 38 is provided between the portion 36c of the electrode pad 36 and the source electrode pad 32 in the Y-direction in plan view.

As shown in FIG. 2, the extraction electrode 40 includes a portion 40a extending in the Y-direction. The extraction electrode 40 includes a portion 40b and a portion 40c extending in the X-direction. The portion 40b is provided in contact with one Y-direction end of the portion 40a. The portion 40c is provided in contact with the other Y-direction end of the portion 40a.

The extraction electrode 42 includes a portion 42a extending in the Y-direction. The extraction electrode 42 includes a portion 42b and a portion 42c extending in the X-direction. The portion 42b is provided in contact with one Y-direction end of the portion 42a. The portion 42c is provided in contact with the other Y-direction end of the portion 42a.

Part of the portion 42b overlaps part of the portion 40b in plan view. Part of the portion 42c overlaps part of the portion 40c in plan view.

At least part of the source electrode pad 32 is provided between the portion 40b and the portion 40c in plan view. At least part of the source electrode pad 32 is provided between the portion 42b and the portion 42c in plan view.

Here, the cross section taken along A-A′ of FIG. 1 is described with reference to FIG. 3.

The drain electrode 30 is provided on a second major surface (back surface). The second major surface is a surface on the opposite side from the first major surface of the substrate 1.

The n-type drain region 10 is provided on the back surface side of the substrate 1. The n-type drain region 10 is electrically connected to the drain electrode 30.

The n-type semiconductor region 12 is provided on the n-type drain region 10. The n-type semiconductor region 12 is electrically connected to the drain electrode 30 through the n-type drain region 10. The n-type carrier density of the n-type semiconductor region 12 is lower than the n-type carrier density of the n-type drain region 10.

The p-type base region 20 is selectively provided on the n-type semiconductor region 12 on the front surface side of the substrate 1.

The n-type source region 22 is selectively provided on the p-type base region 20 on the front surface side of the substrate 1. The n-type carrier density of the n-type source region 22 is higher than the n-type carrier density of the n-type semiconductor region 12. The n-type carrier density of the n-type source region 22 is higher than the p-type carrier density of the p-type base region 20.

The buried electrode 14 is opposed to the n-type semiconductor region 12 across the insulating layer 16. That is, the insulating layer 16 is provided between the n-type semiconductor region 12 and the buried electrode 14.

The gate electrode 24 is opposed to the n-type semiconductor region 12, the p-type base region 20, and the n-type source region 22 across the insulating layer 26. That is, the insulating layer 26 is provided between the n-type semiconductor region 12 and the gate electrode 24, between the p-type base region 20 and the gate electrode 24, and between the n-type source region 22 and the gate electrode 24.

The gate electrode 24 is provided above the buried electrode 14 through the insulating layer 18. That is, the insulating layer 18 is provided between the buried electrode 14 and the gate electrode 24.

The insulating layer 18 and the insulating layer 26 may be a common insulating layer. That is, in this case, the insulating layer 26 corresponds to a region included in a single insulating layer, the region being located between the gate electrode 24 and the n-type semiconductor region 12, between the gate electrode 24 and the p-type base region 20, and between the gate electrode 24 and the n-type source region 22. The insulating layer 18 corresponds to a region included in the single insulating layer, the region being located between the gate electrode 24 and the buried electrode 14.

The buried electrode 14 extends in the Y-direction like the gate electrode 24. The buried electrode 14 is provided in a plurality in the X-direction.

The source electrode pad 32 is provided on the p-type base region 20 and the n-type source region 22. The n-type source region 22 is electrically connected to the source electrode pad 32.

An insulating layer 28 is provided between the gate electrode 24 and the source electrode pad 32.

The drain electrode 30 is applied with a positive potential relative to the potential of the source electrode pad 32. The gate electrode 24 is applied with a voltage higher than or equal to the threshold. This turns on the MOSFET. At this time, a channel (inversion layer) is formed in the region of the p-type base region 20 near the gate insulating layer 26.

On the other hand, the channel formed in the p-type base region 20 vanishes when the voltage applied to the gate electrode 24 is made less than the threshold voltage. This turns off the MOSFET.

Next, the cross section taken along B-B′ of FIG. 1 is described with reference to FIG. 4.

The buried electrode 14 is connected to the portion 40b or 40c of the extraction electrode 40 through a connection part 44. The connection part 44 is a conductive layer provided between the extraction electrode 40 and the buried electrode 14 and extending in the Z-direction.

The gate electrode 24 is connected to the portion 42b or 42c of the extraction electrode 42 through a connection part 46. The connection part 46 is a conductive layer provided between the gate electrode 24 and the extraction electrode 42 and extending in the Z-direction.

The extraction electrode 40 is connected to the portions 36b and 36c of the electrode pad 36. The extraction electrode 40 is connected to the electrode pad 36 through a connection part 35. The connection part 35 penetrates through the insulating layer provided between the extraction electrode 40 and the electrode pad 36.

The extraction electrode 40 is located between part of the buried electrode 14 and the electrode pad 36 as viewed in the Y-direction. That is, at least part of the extraction electrode 40 overlaps part of the buried electrode 14 in the Z-direction. At least part of the extraction electrode 40 overlaps part of the electrode pad 36 in the Z-direction.

The buried electrode 14 may be connected to the electrode pad 36 through the connection part 44 without the intermediary of the extraction electrode 40 and the connection part 35.

The extraction electrode 42 is connected to the portions 38b and 38c of the gate electrode pad 38. The extraction electrode 42 is connected to the gate electrode pad 38 through a connection part 37. The connection part 37 penetrates through the insulating layer provided between the extraction electrode 42 and the gate electrode pad 38.

The extraction electrode 42 is located between the gate electrode 24 and the gate electrode pad 38 as viewed in the Y-direction. That is, at least part of the extraction electrode 42 overlaps part of the gate electrode 24 in the Z-direction. At least part of the extraction electrode 42 overlaps part of the gate electrode pad 38 in the Z-direction.

The gate electrode 24 may be connected to the gate electrode pad 38 through the connection part 46 without the intermediary of the extraction electrode 42 and the connection part 37.

An insulating layer 39 is provided between the extraction electrode 40 and the front surface of the substrate 1. An insulating layer 41 is provided between the extraction electrode 40 and the extraction electrode 42. At least part of the extraction electrode 40 overlaps at least part of the extraction electrode 42 in the Z-direction.

At least part of the extraction electrode 40 and at least part of the extraction electrode 42 overlap the source electrode pad 32 in the Y-direction.

As shown in FIG. 5, part of the buried electrodes 14 and part of the gate electrodes 24 are provided below the portion 36d of the electrode pad 36.

The portion 40a of the extraction electrode 40 is connected to the portion 36a of the electrode pad 36 through the connection part 35.

As shown in FIG. 6, part of the buried electrodes 14 and part of the gate electrodes 24 are provided below the portion 38d of the gate electrode pad 38.

The portion 42a of the extraction electrode 42 is connected to the portion 38a of the gate electrode pad 38 through the connection part 37.

Here, materials usable in the above configuration are described.

The substrate 1 is made of semiconductor such as silicon, compound semiconductor such as silicon carbide (SiC) or gallium nitride (GaN), or wide bandgap semiconductor such as diamond.

Each semiconductor region is e.g. an impurity region formed in the substrate 1 made of the aforementioned material. The p-type impurity is e.g. boron. The n-type impurity is e.g. phosphorus or arsenic.

The buried electrode 14 and the gate electrode 24 are made of e.g. polysilicon. The polysilicon may be doped with n-type or p-type impurity.

The electrode, the wiring, and the connection part are made of a conductive material such as copper, aluminum, silver, gold, vanadium, nickel, or tin.

Each insulating layer is made of e.g. silicon oxide, silicon nitride, or silicon oxynitride.

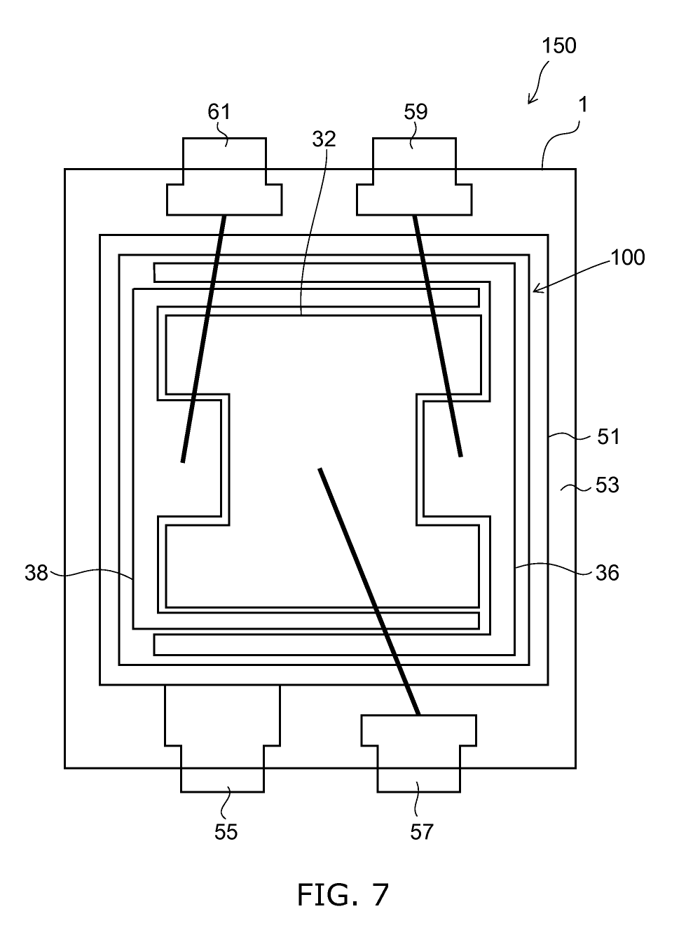

FIG. 7 is a schematic view showing the packaged semiconductor device according to the first embodiment.

The semiconductor device 100 is packaged in a semiconductor package 150. The semiconductor package 150 includes the semiconductor device 100, a frame 51, a sealing member 53, and terminals 55, 57, 59, and 61.

The frame 51 is intended for mounting the substrate 1 thereon. The frame 51 is electrically connected to the drain electrode 30 of the semiconductor device 100.

The sealing member 53 seals the semiconductor device 100 provided on the frame 51. The sealing member 53 can be made of e.g. resin.

The terminal 55 is connected to the frame 51. That is, the terminal 55 is electrically connected to the drain electrode 30.

The terminal 57 is connected to the source electrode pad 32.

The terminal 59 is connected to the electrode pad 36.

The terminal 61 is connected to the gate electrode pad 38.

Next, an example method for manufacturing the semiconductor device 100 according to this embodiment is described.

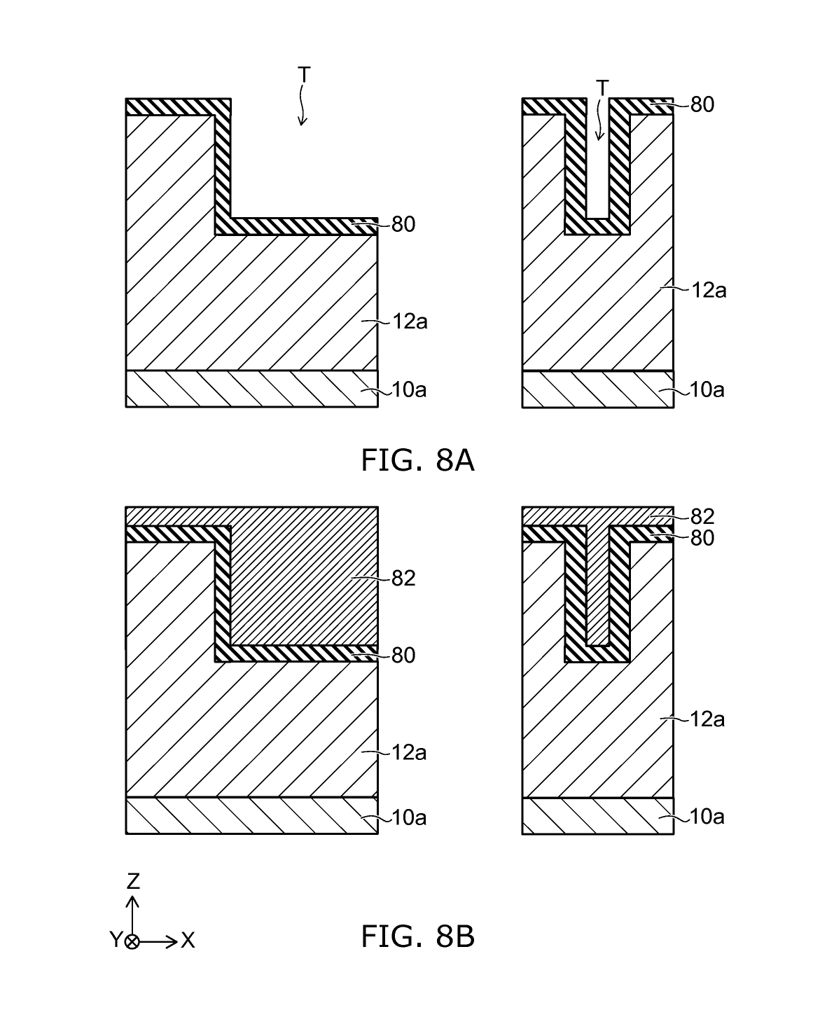

FIGS. 8A to 14B are schematic process sectional views showing the process for manufacturing the semiconductor device 100 according to this embodiment.

In FIGS. 8A to 14B, the left figure shows a cross section at the position corresponding to the cross section taken along B-B′ of FIG. 1. The right figure shows a cross section at the position corresponding to the cross section taken along A-A′ of FIG. 1.

First, an n-type semiconductor substrate 10a is prepared. The substrate 10a is e.g. a substrate composed primarily of Si. Next, Si is epitaxially grown on the substrate 10a while adding an n-type impurity. Thus, an n-type semiconductor region 12a is formed. Next, a trench T is formed in the n-type semiconductor region 12a.

The trench T is formed by e.g. IBE (ion beam etching) technique or RIE (reactive ion etching) technique. Then, as shown in FIG. 8A, an insulating layer 80 is formed on the surface of the substrate 1 and the inner wall of the trench T. The insulating layer 80 is made of e.g. silicon oxide.

This step forms an insulating layer 16 and an insulating layer 39.

Next, as shown in FIG. 8B, a conductive layer 82 is formed on the insulating layer 80. The trench T is buried with the conductive layer 82. The conductive layer 82 is e.g. a polycrystalline silicon layer.

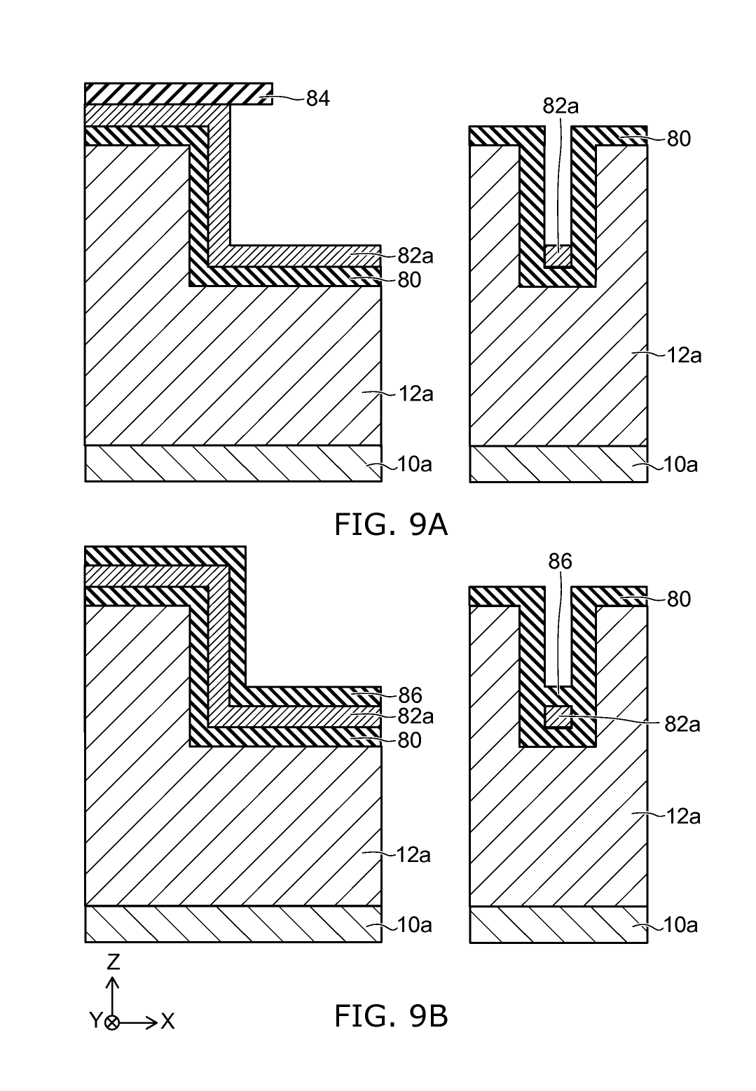

Next, a mask 84 is formed on a region of the surface of the substrate 1 other than the region in which the trench T is formed. As shown in FIG. 9A, the mask 84 may be projected from the outer edge of the trench T toward the inside of the trench T.

Next, as shown in FIG. 9A, part of the portion of the conductive layer 82 formed in the trench T is removed by e.g. wet etching technique using the mask 84. The removal of the conductive layer 82 may be performed by CDE (chemical dry etching) technique. This step forms a conductive layer 82a on the insulating layer 80.

This step forms a buried electrode 14, a connection part 44, and an extraction electrode 40.

Next, the mask 84 is removed. Then, as shown in FIG. 9B, an insulating layer 86 is formed on the conductive layer 82a. The insulating layer 86 is made of e.g. silicon oxide.

This step forms an insulating layer 18 and an insulating layer 41.

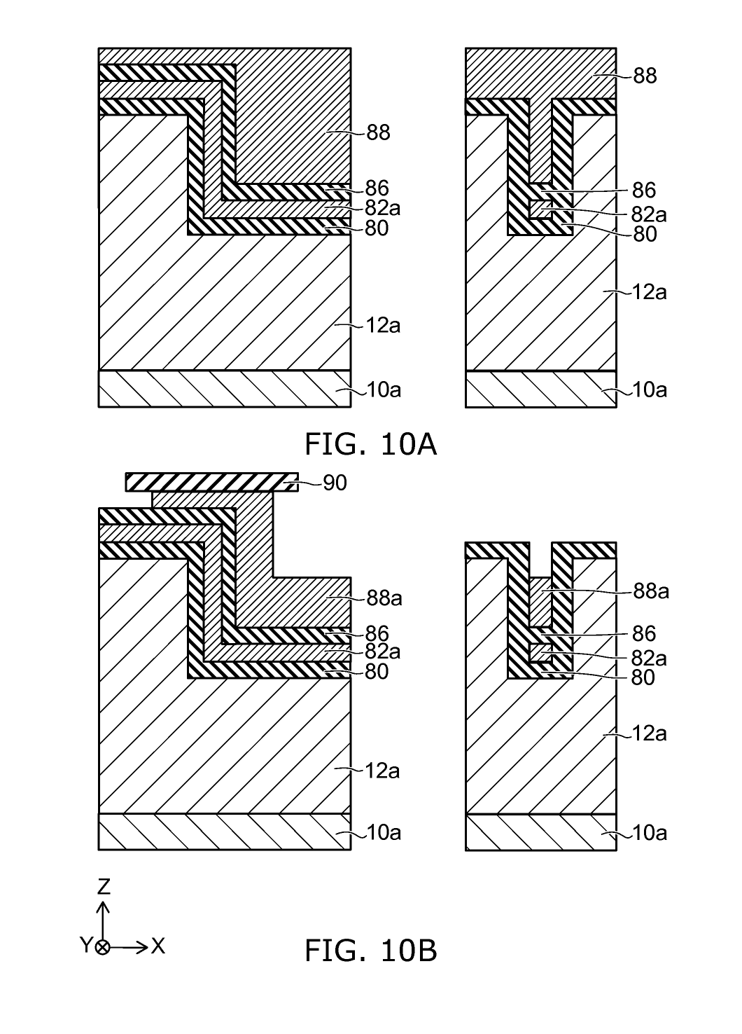

Next, as shown in FIG. 10A, a conductive layer 88 is formed on the insulating layer 86. The trench T is buried with the conductive layer 88. The conductive layer 88 is e.g. a polycrystalline silicon layer.

Next, a mask 90 covering the outer edge portion of the trench T is formed. In the Z-direction, the mask 90 overlaps the portion extending in the Z-direction of the insulating layer 80 provided on the sidewall of the trench T. In the Z-direction, the mask 90 overlaps the portion of the conductive layer 82a extending in the Z-direction and the portion of the insulating layer 86 extending in the Z-direction.

Next, as shown in FIG. 10B, part of the conductive layer 88 is removed by e.g. wet etching technique using the mask 90. This step forms a conductive layer 88a on the insulating layer 86.

This step forms a gate electrode 24, a connection part 46, and an extraction electrode 42.

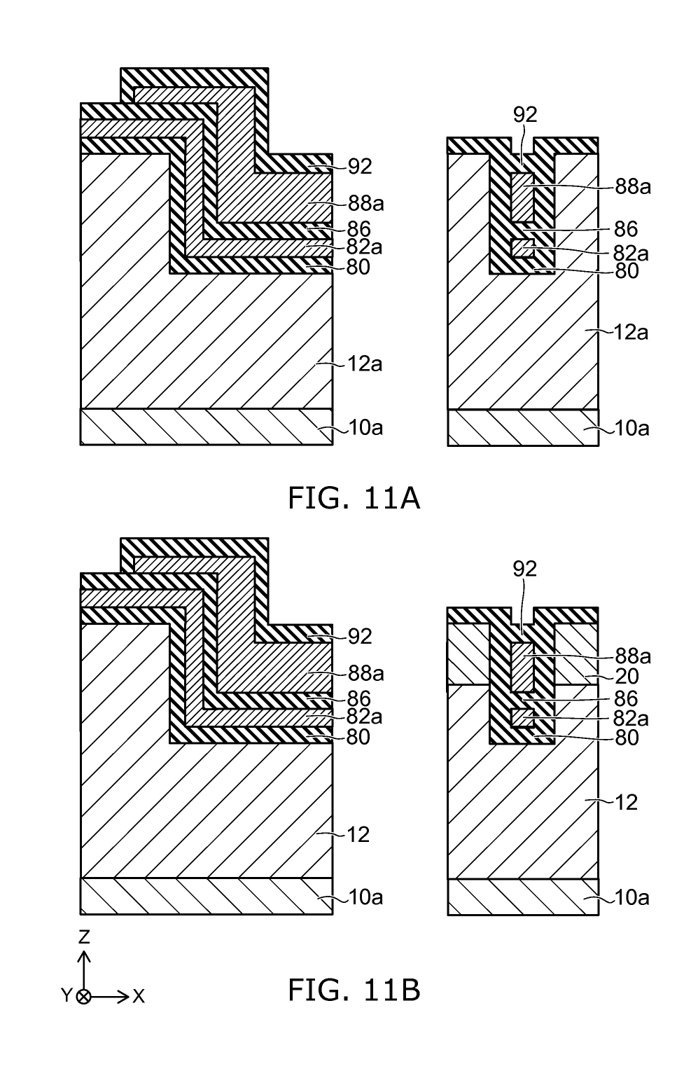

Next, the mask 90 is removed. Then, as shown in FIG. 11A, an insulating layer 92 is formed on the conductive layer 88a. The insulating layer 92 is made of e.g. silicon oxide.

Next, a p-type impurity is ion implanted into the surface portion of the n-type semiconductor region 12a. Thus, as shown in FIG. 11B, a p-type base region 20 is formed. The region of the n-type semiconductor region 12a other than the region in which the p-type base region 20 is formed corresponds to the n-type semiconductor region 12 shown in FIGS. 3 to 6.

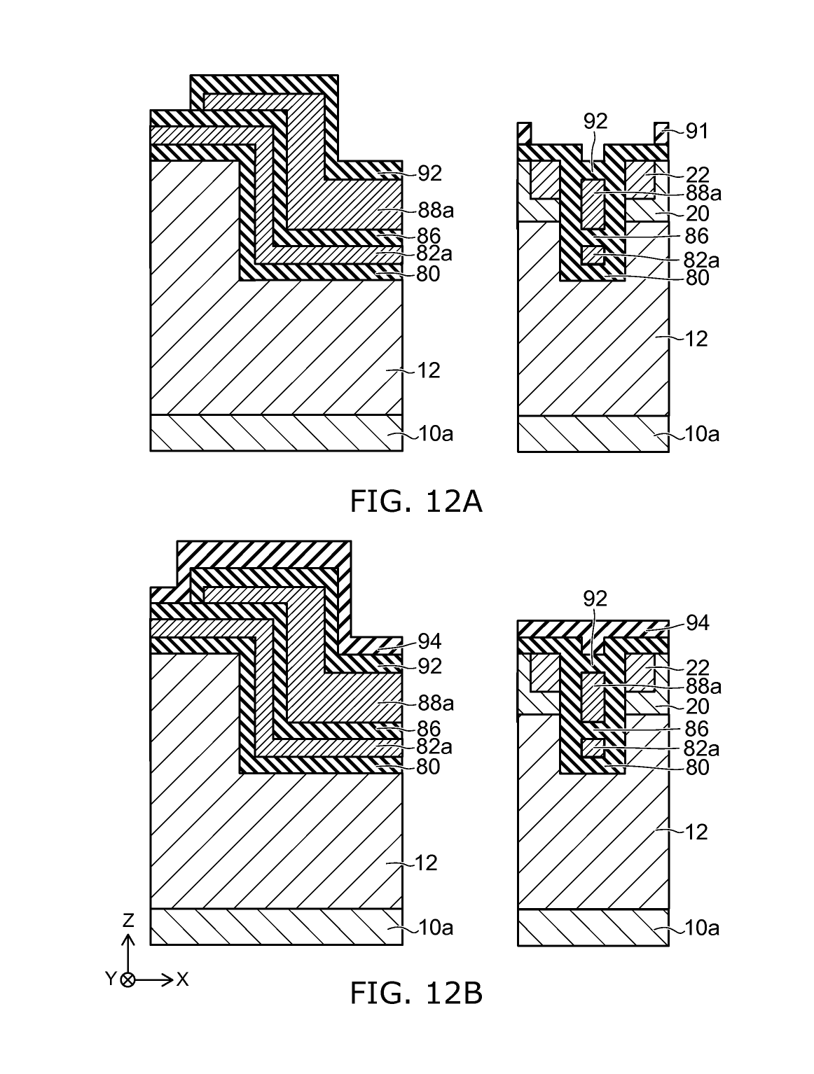

Next, a mask 91 covering part of the insulating layer 92 is formed. A p-type impurity is ion implanted selectively into the surface of the p-type base region 20 using the mask 91. Thus, as shown in FIG. 12A, an n-type source region 22 is formed.

Next, as shown in FIG. 12B, an insulating layer 94 as a protective film is formed on the insulating layer 92. The insulating layer 92 and the insulating layer 94 form the insulating layer 28 shown in FIG. 4. The insulating layer 94 is made of e.g. silicon oxide.

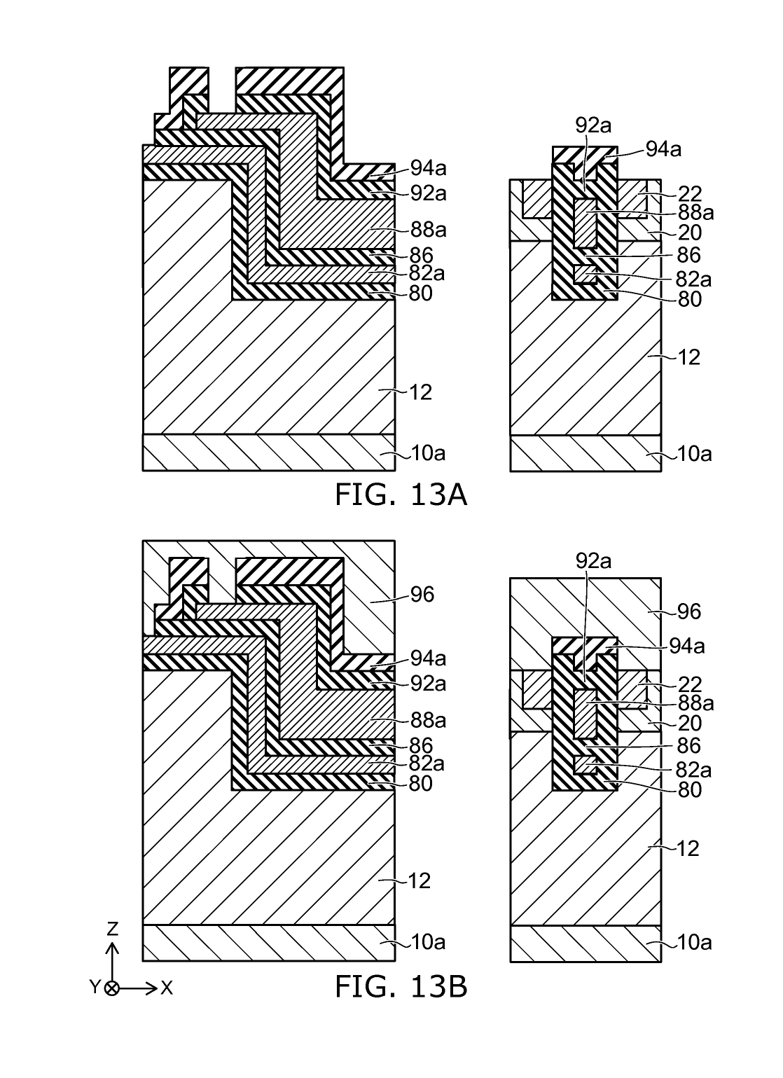

Next, as shown in FIG. 13A, part of the insulating layer 86, part of the insulating layer 92, and part of the insulating layer 94 are removed by e.g. RIE technique. This step exposes part of the conductive layer 82a, part of the conductive layer 88a, the p-type base region 20, and the n-type source region 22.

Next, as shown in FIG. 13B, a conductive layer 96 is formed. The conductive layer 96 is formed in contact with the p-type base region 20, the n-type source region 22, part of the conductive layer 82a, and part of the conductive layer 88a. The conductive layer 96 is e.g. a metal-containing layer.

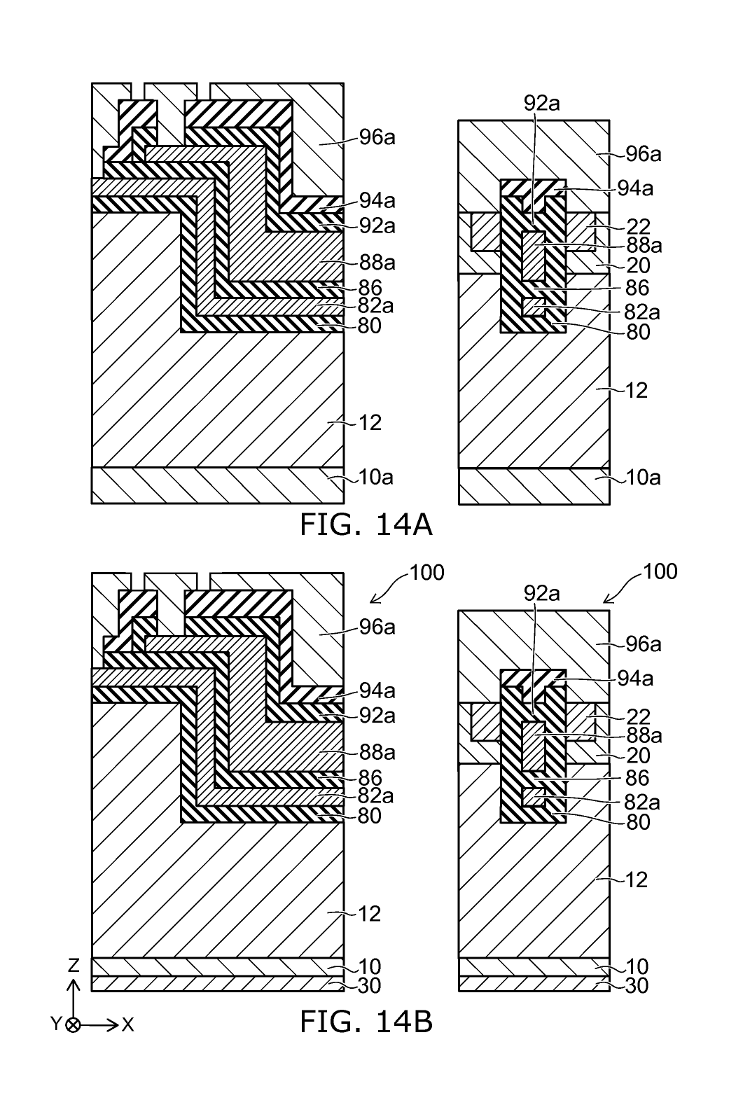

Next, as shown in FIG. 14A, part of the conductive layer 96 is removed by e.g. RIE technique. This step forms a source electrode pad 32, an electrode pad 36, and a gate electrode pad 38.

Next, the back surface of the substrate 10a is polished to form an n-type drain region 10. Next, a metal layer is formed on the n-type drain region 10. Thus, a drain electrode 30 is formed. The semiconductor device 100 shown in FIG. 14B is obtained by the following steps.

The aforementioned layers can be formed by e.g. CVD (chemical vapor deposition) technique or PVD (physical vapor deposition) technique.

The insulating layer 80 may be formed by oxidizing the surface of the substrate 1 and the inner wall of the trench T. The insulating layer 86 may be formed by oxidizing the surface of the conductive layer 82a. The insulating layer 92 may be formed by oxidizing the surface of the conductive layer 88a.

Next, the function and effect of this embodiment are described.

The semiconductor device according to this embodiment includes a buried electrode 14. The buried electrode 14 is connected to the electrode pad 36 separated from the source electrode pad 32 and the gate electrode pad 38. According to this configuration, the potential of the buried electrode 14 can be set by connecting the electrode pad 36 to a desired potential.

Here, the relationship between the potential of the buried electrode 14 and the characteristics of the semiconductor device 100 is described in detail.

First, the relationship is described in the case where the buried electrode 14 is electrically connected to the gate electrode 24.

In this case, when the gate electrode 24 is applied with a voltage higher than or equal to the threshold, the buried electrode 14 is also applied with a similar voltage. Application of voltage to the buried electrode 14 increases the density of electrons near the insulating layer 16 in the n-type semiconductor region 12. This decreases the resistance for the electrons passing through the n-type semiconductor region 12. Thus, the on-resistance of the semiconductor device 100 is reduced.

That is, in the case where the buried electrode 14 is electrically connected to the gate electrode 24, power consumption due to on-resistance can be made lower.

Next, the relationship is described in the case where the buried electrode 14 is not electrically connected to the gate electrode 24, but connected to another potential, e.g., the source electrode pad 32.

In this case, the gate-drain capacitance is lower than in the case where the buried electrode 14 is connected to the gate electrode 24. Thus, the on-resistance is higher than in the case where the buried electrode 14 is electrically connected to the gate electrode 24. However, the switching loss is reduced by the decrease of the gate-drain capacitance.

That is, in the case where the buried electrode 14 is not connected to the gate electrode 24, power consumption due to switching loss can be made lower than in the case where the buried electrode 14 is connected to the gate electrode 24.

As described above, the characteristics of the semiconductor device are improved in accordance with the potential of the buried electrode 14. However, for instance, in the case of frequent repetition of on-off switching in the semiconductor device 100 in which the buried electrode 14 is connected to the gate electrode 24, the increase of power consumption due to the increase of switching loss surpasses the reduction of power consumption due to the reduction of on-resistance.

Alternatively, in the case of low frequency of switching in the semiconductor device 100 in which the buried electrode 14 is not connected to the gate electrode 24, the increase of power consumption due to the increase of on-resistance surpasses the reduction of power consumption due to the reduction of switching loss.

Thus, preferably, the potential of the buried electrode 14 is set depending on the usage mode of the semiconductor device 100.

According to this embodiment, the buried electrode 14 is connected through the extraction electrode 40 to the electrode pad 36 separated from the source electrode pad 32 and the gate electrode pad 38. Thus, the buried electrode 14 can be connected to a suitable potential depending on the usage mode of the semiconductor device 100.

The extraction electrode 40 includes the portion 40b. The electrode pad 36 includes the portion 36b. The portion 40b is connected to the portion 36b. This can increase the contact area between the extraction electrode 40 and the electrode pad 36. Likewise, the extraction electrode 40 includes the portion 40c. The electrode pad 36 includes the portion 36c. The portion 40c is connected to the portion 36c. This can increase the contact area between the extraction electrode 40 and the electrode pad 36.

The resistance between the extraction electrode 40 and the electrode pad 36 can be reduced by increasing the contact area between the extraction electrode 40 and the electrode pad 36. The reduction of the resistance between the extraction electrode 40 and the electrode pad 36 can improve e.g. the rate of switching on/off the MOSFET in the case where the buried electrode 14 is connected to the gate electrode 24.

The extraction electrode 42 includes the portion 42b. The gate electrode pad 38 includes the portion 38b. The portion 42b is connected to the portion 38b. This can increase the contact area between the extraction electrode 42 and the gate electrode pad 38. Likewise, the extraction electrode 42 includes the portion 42c. The gate electrode pad 38 includes the portion 38c. The portion 42c is connected to the portion 38c. This can increase the contact area between the extraction electrode 42 and the gate electrode pad 38.

The resistance between the extraction electrode 42 and the gate electrode pad 38 can be reduced by increasing the contact area between the extraction electrode 42 and the gate electrode pad 38. The reduction of the resistance between the extraction electrode 42 and the gate electrode pad 38 can improve the rate of switching on/off the MOSFET.

The electrode pad 36 includes the projected portion 36d. Thus, in the case where the electrode pad 36 is connected to the terminal 59 by a metal wiring, the contact area between the electrode pad 36 and the metal wiring can be increased. This can reduce the resistance between the electrode pad 36 and the terminal 59.

The distance between the portion 36b and the source electrode pad 32 is larger than the distance between the portion 38b and the source electrode pad 32. This facilitates connecting the electrode pad 36 to the buried electrode 14.

The reason for this is as follows.

The buried electrode 14 connected to the electrode pad 36 is located below the gate electrode 24 connected to the gate electrode pad 38. Consider the case where the distance between the portion 36b and the source electrode pad 32 is smaller than the distance between the portion 38b and the source electrode pad 32. In this case, connecting the buried electrode 14 to the electrode pad 36 requires formation of a connection part penetrating through the extraction electrode 42, or formation of a wiring avoiding the extraction electrode 42.

This complicates the wiring structure and also makes it difficult to fabricate the semiconductor device. In the case where the distance between the portion 36b and the source electrode pad 32 is larger than the distance between the portion 38b and the source electrode pad 32, connection between the electrode pad 36 and the buried electrode 14 can be realized in a simpler wiring structure.

Furthermore, in the semiconductor package 150 including the semiconductor device 100, the drain electrode 30, the source electrode pad 32, the electrode pad 36, and the gate electrode pad 38 are connected to different terminals, respectively. Thus, when the semiconductor device 100 is connected to another circuit, the terminal connected to the electrode pad 36 is easily connected to a terminal having a desired potential.

### Second Embodiment

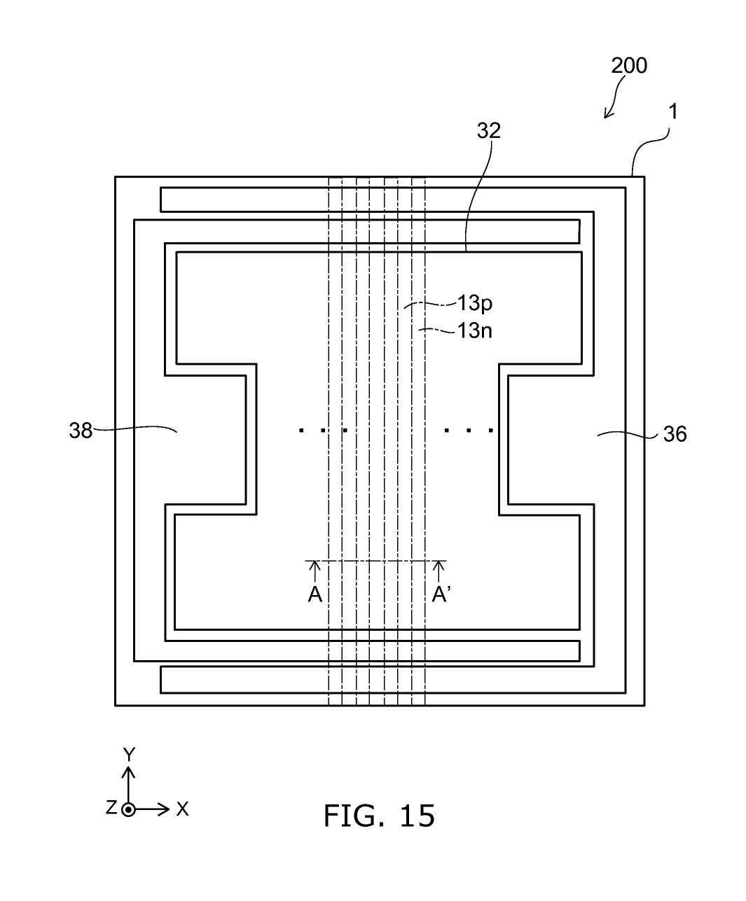

FIG. 15 is a schematic plan view showing part of a semiconductor device 200 according to a second embodiment.

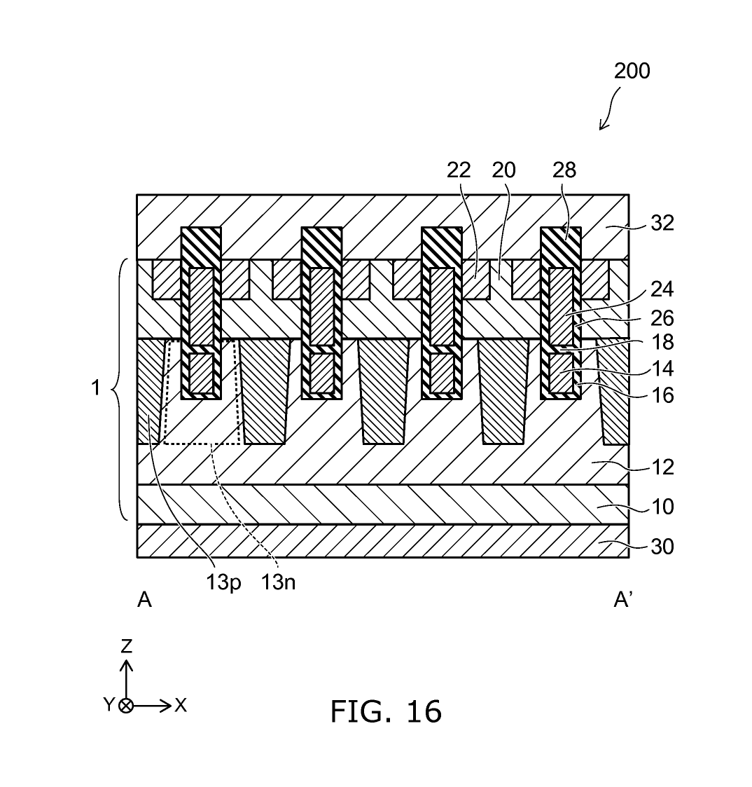

FIG. 16 is a schematic sectional view taken along A-A′ of FIG. 15, showing part of the semiconductor device 200 according to the second embodiment.

In FIG. 15, the insulating layers are not shown.

The semiconductor device 200 according to this embodiment is different from the semiconductor device 100 primarily in including a super-junction structure composed of an n-type pillar 13n and a p-type pillar 13p.

The n-type pillar 13n extends in the Y-direction. The n-type pillar 13n is selectively provided on the n-type semiconductor region 12. The n-type pillar 13n is provided in a plurality in the X-direction.

The n-type carrier density of the n-type pillar 13n is equal to or higher than e.g. the n-type carrier density of the n-type semiconductor region 12.

The p-type pillar 13p extends in the Y-direction. The p-type pillar 13p is selectively provided on the n-type semiconductor region 12. The p-type pillar 13p is provided in a plurality in the X-direction.

The p-type carrier density of the p-type pillar 13p is equal to e.g. the n-type carrier density of the n-type pillar 13n.

The p-type carrier density of the p-type pillar 13p is equal to or higher than e.g. the n-type carrier density of the n-type semiconductor region 12.

The n-type pillars 13n and the p-type pillars 13p are provided alternately in the Y-direction. In other words, the p-type pillar 13p is provided between the adjacent n-type pillars 13n. The n-type pillar 13n is provided between the adjacent p-type pillars 13p.

As shown in FIG. 15, part of the n-type pillar 13n and part of the p-type pillar 13p overlap the portions 36b and 36c of the electrode pad 36 in plan view. Part of the n-type pillar 13n and part of the p-type pillar 13p overlap the portions 38b and 38c of the gate electrode pad 38 in plan view.

The extending direction of the n-type pillar 13n and the p-type pillar 13p is the same as the extending direction of e.g. the portion 36a and the portion 38a.

Like the first embodiment, this embodiment also includes the electrode pad 36 separated from the source electrode pad 32 and the gate electrode pad 38. Thus, the buried electrode 14 can be connected to a suitable potential depending on the usage mode of the semiconductor device 200.

Furthermore, this embodiment includes a super-junction structure composed of n-type pillars 13n and p-type pillars 13p. Thus, the breakdown voltage can be made higher than that of the semiconductor device according to the first embodiment.

### Third Embodiment

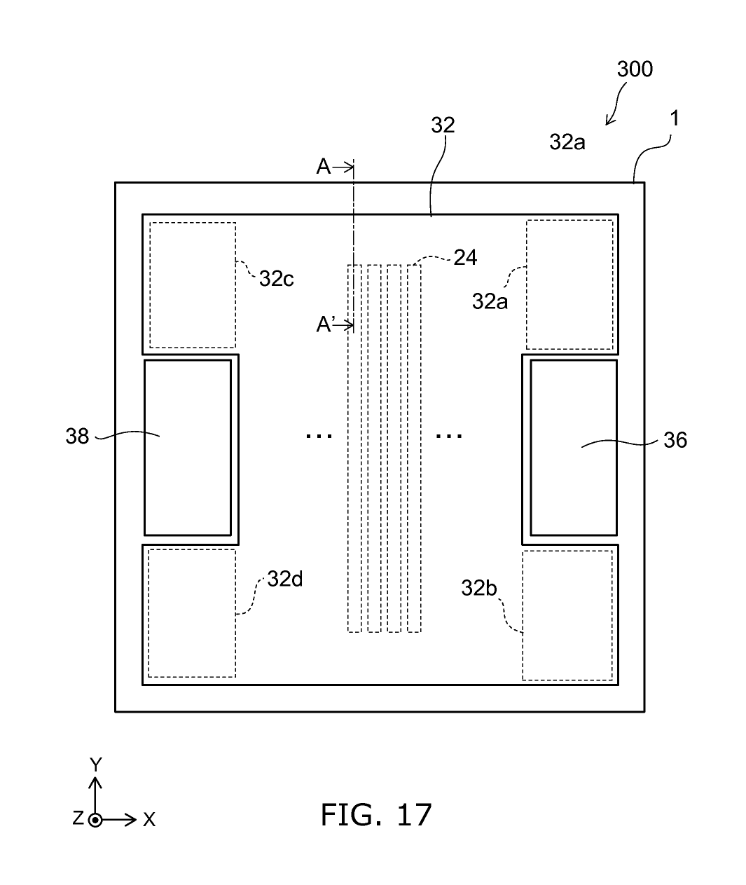

FIG. 17 is a schematic plan view showing part of a semiconductor device 300 according to a third embodiment.

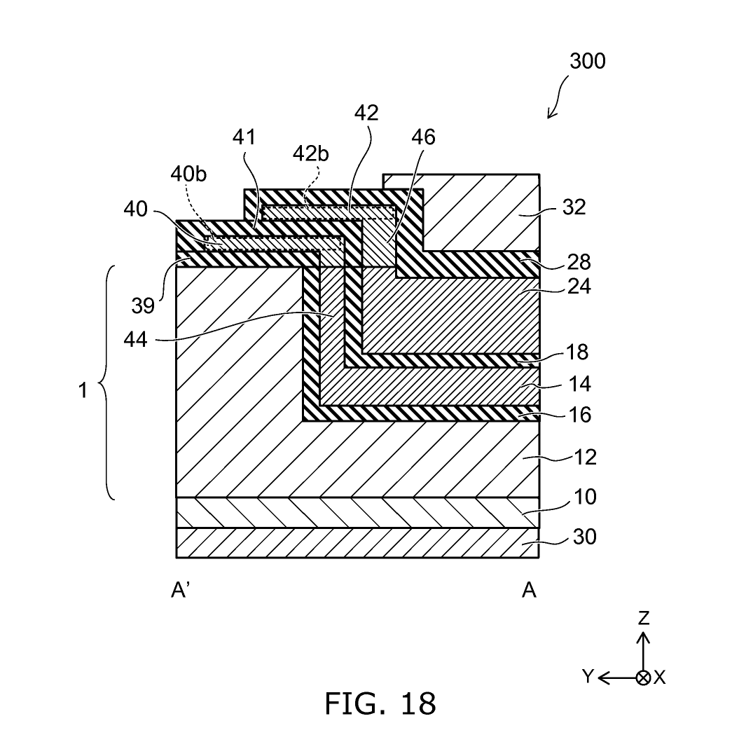

FIG. 18 is a schematic sectional view taken along A-A′ of FIG. 17, showing part of the semiconductor device 300 according to the third embodiment.

In FIG. 17, the insulating layers are not shown.

The semiconductor device 300 according to this embodiment is different from the semiconductor device 100 primarily in the shape of the electrode pad 36 and the gate electrode pad 38.

In the semiconductor device 100, the electrode pad 36 includes the portions 36a-d, and the gate electrode pad 38 includes the portions 38a-d. In contrast, in the semiconductor device 300, the electrode pad 36 includes a portion 36d provided between the portion 32a and the portion 32b of the source electrode. The gate electrode pad 38 includes a portion 38d provided between the portion 32c and the portion 32d.

As shown in FIG. 18, in the A-A′ cross section, the extraction electrode 40 is not connected to the electrode pad 36. The extraction electrode 42 is not connected to the gate electrode pad 38. In the semiconductor device 300, the structure of the portion provided with the electrode pad 36 is similar to the structure shown in FIG. 5. In the semiconductor device 300, the structure of the portion provided with the gate electrode pad 38 is similar to the structure shown in FIG. 6.

Also in this embodiment, as in the first embodiment, the buried electrode 14 can be connected to a suitable potential depending on the usage mode of the semiconductor device 300.

### Fourth Embodiment

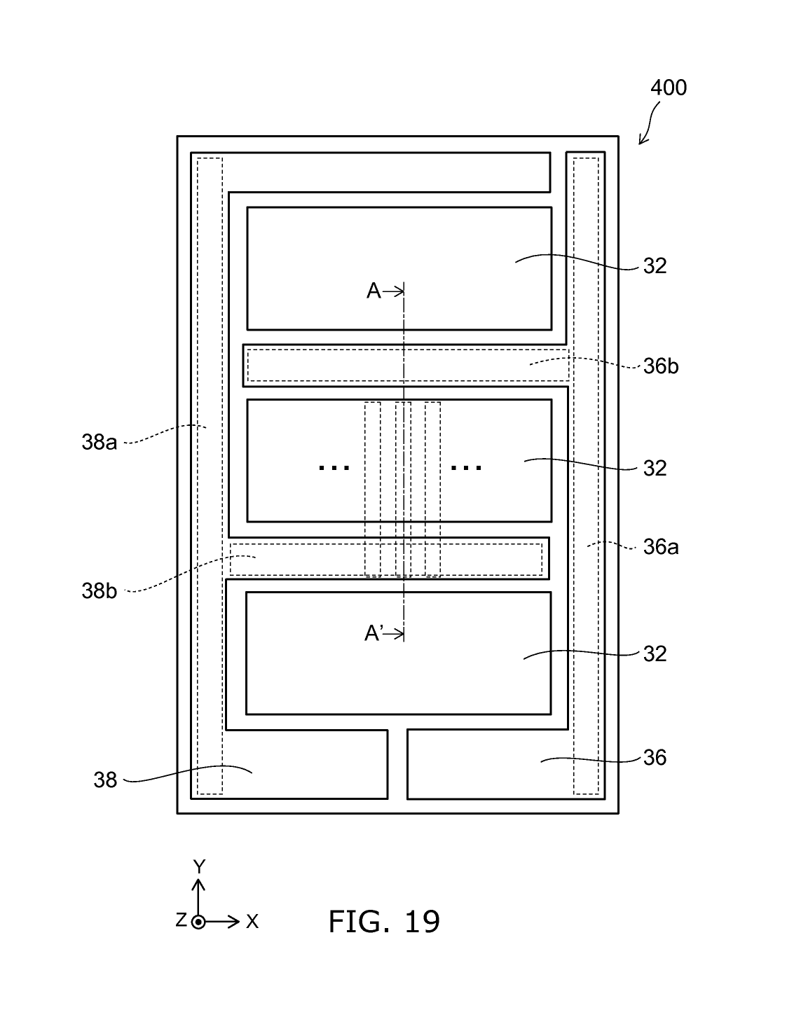

FIG. 19 is a schematic plan view showing part of a semiconductor device 400 according to a fourth embodiment.

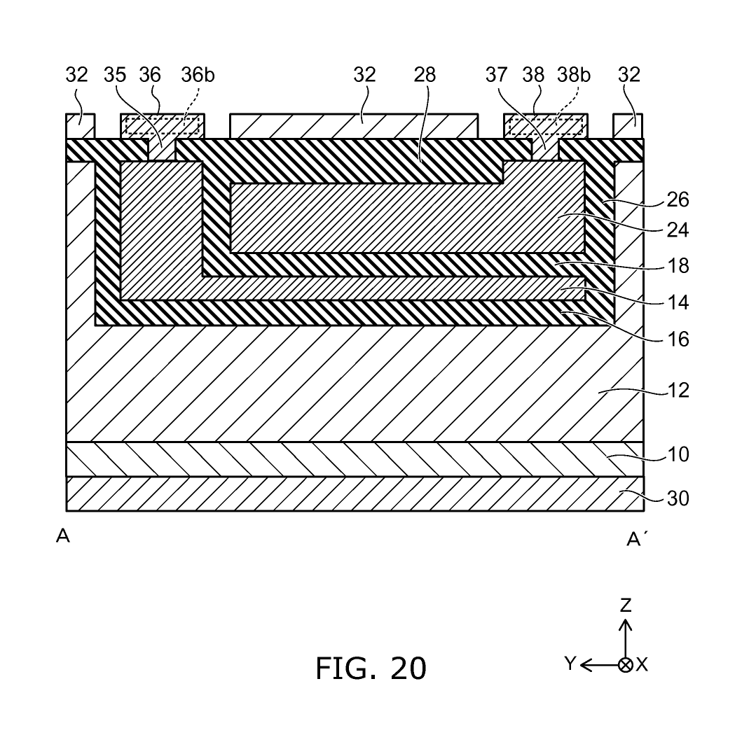

FIG. 20 is a schematic sectional view taken along A-A′ of FIG. 19, showing part of the semiconductor device 400 according to the fourth embodiment.

In FIG. 19, the insulating layers are not shown. In FIG. 19, part of the gate electrodes 24 provided in a plurality are shown by dashed lines.

The semiconductor device 400 includes a plurality of source electrode pads 32 as shown in e.g. FIG. 19. As an example, the plurality of source electrode pads 32 are provided between the electrode pad 36 and the gate electrode pad 38 in plan view.

The electrode pad 36 includes a portion 36a extending in the Y-direction and a portion 36b extending in the X-direction. The gate electrode pad 38 includes a portion 38a extending in the Y-direction and a portion 38b extending in the X-direction.

The portion 36a and the portion 38a extend in parallel to e.g. the gate electrode 24. The portion 38b overlaps a plurality of gate electrodes 24 in the Z-direction.

As an example, in plan view, a plurality of source electrode pads 32 are provided between the portion 36a and the portion 38a in the X-direction. However, only one source electrode pad 32 may be provided between the portion 36a and the portion 38a in the X-direction. At least one of the plurality of source electrode pads 32 is provided between the portion 36b and the portion 38b in e.g. the Y-direction in plan view.

As shown in FIG. 20, the buried electrode 14 is connected to the portion 36b of the electrode pad 36 through a connection part 35. The gate electrode 24 is connected to the portion 38b of the gate electrode pad 38 through a connection part 37. At least part of the insulating layer 28 provided between the gate electrode 24 and the source electrode pad 32 is provided between the connection parts 35 and 37.

Also in this embodiment, as in the first embodiment, the buried electrode 14 can be connected to a suitable potential depending on the usage mode of the semiconductor device 400.

### Fifth Embodiment

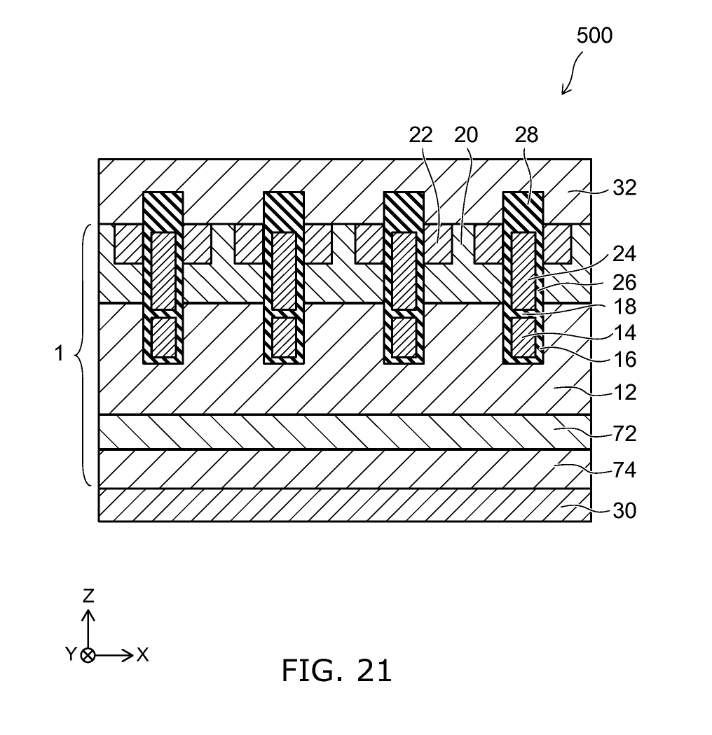

FIG. 21 is a schematic sectional view showing part of a semiconductor device 500 according to a fifth embodiment.

In FIG. 21, components that can be configured similarly to those of the first embodiment are labeled with the same reference numerals as in FIG. 3, and the detailed description thereof is omitted appropriately.

The semiconductor device 500 according to the fifth embodiment includes e.g. an IGBT.

The semiconductor device 500 includes an n-type buffer region 72 and a p-type collector region 74 instead of the n-type drain region 10 in the semiconductor device 100. The semiconductor device 500 includes an n-type emitter region 22, a collector electrode 30, and an emitter electrode pad 32.

The n-type carrier density of the n-type buffer region 72 is higher than the n-type carrier density of the n-type semiconductor region 12. The p-type carrier density of the p-type collector region 74 is higher than the n-type carrier density of the n-type semiconductor region 12. The p-type carrier density of the p-type collector region 74 is equal to e.g. the n-type carrier density of the n-type buffer region 72.

The n-type buffer region 72 is provided on the p-type collector region 74. The p-type collector region 74 is electrically connected to the collector electrode 30. The n-type emitter region 22 is electrically connected to the emitter electrode pad 32.

Also in this embodiment, as in the first embodiment, the buried electrode 14 can be connected to a suitable potential depending on the usage mode of the semiconductor device 500.

The embodiments according to the invention have been described with reference to “carrier density”. The carrier density refers to the density of activated impurities among the impurities contained in the semiconductor. The carrier density may be regarded as being synonymous with the concentration of activated impurities. Thus, the carrier density in the description of the above embodiments may be replaced by impurity concentration. The carrier density may be replaced by carrier concentration. The carrier density can be qualitatively analyzed by e.g. scanning capacitance microscopy (SCM). The impurity concentration can be quantitatively analyzed by e.g. secondary ion mass spectrometry (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first semiconductor region of a first conductivity type;
a second semiconductor region of a second conductivity type selectively provided on the first semiconductor region;
a third semiconductor region of the first conductivity type selectively provided on the second semiconductor region;
a first electrode provided in the first semiconductor region through a first insulating layer;
a gate electrode provided on the first electrode through a second insulating layer;
a third insulating layer provided between the gate electrode and the first semiconductor region, between the gate electrode and the second semiconductor region, and between the gate electrode and the third semiconductor region;
a second electrode electrically connected to the third semiconductor region;
a third electrode spaced from the second electrode and electrically connected to the gate electrode; and
a fourth electrode electrically connected to the first electrode and spaced from the second electrode and the third electrode.

2. The device according to claim 1, wherein
the first semiconductor region, the second semiconductor region, and the third semiconductor region are regions provided in a semiconductor substrate having a first surface, and
the second electrode, the third electrode, and the fourth electrode are provided on the first surface.

3. The device according to claim 2, wherein
the first electrode is provided in a plurality,
the gate electrode is provided in a plurality,
each of the first electrodes and each of the gate electrodes extend in a first direction parallel to the first surface,
the plurality of first electrodes and the plurality of gate electrodes are arranged in a second direction parallel to the first surface and orthogonal to the first direction,
each of the gate electrodes is electrically connected to the third electrode, and
each of the first electrodes is electrically connected to the fourth electrode.

4. The device according to claim 3, wherein
the third electrode includes a second portion extending in the first direction,
the fourth electrode includes a second portion extending in the first direction, and
at least part of the second electrode is provided between the second portion of the third electrode and the second portion of the fourth electrode as viewed in a third direction orthogonal to the first surface.

5. The device according to claim 4, wherein
the second electrode includes a first portion and a second portion projected in the second direction, and a third portion and a fourth portion projected in a fourth direction opposite to the second direction,
the third electrode includes a first portion provided between the first portion and the second portion of the second electrode as viewed in the third direction, and
the fourth electrode includes a first portion provided between the third portion and the fourth portion of the second electrode as viewed in the third direction.

6. The device according to claim 5, wherein
the third electrode includes:
a third portion extending in the second direction and connected to one end in the first direction of the second portion of the third electrode; and
a fourth portion extending in the second direction and connected to another end in the first direction of the second portion of the third electrode, and
at least part of the second electrode is provided between the third portion and the fourth portion of the third electrode as viewed in the third direction.

7. The device according to claim 6, wherein
the fourth electrode includes:
a third portion extending in the second direction and connected to one end in the first direction of the second portion of the fourth electrode; and
a fourth portion extending in the second direction and connected to another end in the first direction of the second portion of the fourth electrode, and
at least part of the second electrode is provided between the third portion and the fourth portion of the fourth electrode as viewed in the third direction.

8. The device according to claim 7, wherein at least part of the third portion of the third electrode is provided between the second electrode and the fourth electrode as viewed in the third direction.

9. The device according to claim 7, further comprising:
a first extraction electrode electrically connected to the plurality of gate electrodes and the third electrode,
wherein the first extraction electrode includes a first portion extending in the first direction, and
at least part of the second portion of the third electrode overlaps at least part of the first portion of the first extraction electrode as viewed in the third direction.

10. The device according to claim 9, further comprising:
a second extraction electrode electrically connected to the plurality of first electrodes and the fourth electrode,
wherein the second extraction electrode includes a first portion extending in the first direction, and
at least part of the second portion of the fourth electrode overlaps at least part of the first portion of the second extraction electrode as viewed in the third direction.

11. The device according to claim 10, wherein at least part of the first portion of the first extraction electrode overlaps at least part of the first portion of the second extraction electrode as viewed in the third direction.

12. The device according to claim 4, wherein
the second electrode is provided in a plurality in the first direction, and
the plurality of second electrodes are provided between the second portion of the third electrode and the second portion of the fourth electrode.

13. The device according to claim 12, wherein
the third electrode includes a third portion extending in the second direction,
the fourth electrode includes a third portion extending in the second direction, and
at least one of the plurality of second electrodes is provided between the third portion of the third electrode and the third portion of the fourth electrode.

14. The device according to claim 2, further comprising:
a fifth electrode,
wherein the semiconductor substrate further has a second surface on opposite side from the first surface, and
the fifth electrode is provided on the second surface and electrically connected to the first semiconductor region.

15. The device according to claim 1, further comprising:
a fourth semiconductor region of the second conductivity type provided below the first semiconductor region, carrier density of the second conductivity type of the fourth semiconductor region being higher than carrier density of the second conductivity type of the second semiconductor region.

16. A semiconductor package comprising:
the semiconductor device according to claim 1;
a sealing member sealing the semiconductor device;
a fifth electrode electrically connected to the first semiconductor region;
a first terminal connected to the fifth electrode;
a second terminal connected to the second electrode;
a third terminal connected to the third electrode; and
a fourth terminal connected to the fourth electrode.
